(19) United States
(12) Patent Application Publication
(10) Pub. No.: US 2018/0144277 A1
(43) Pub. Date: May 24, 2018

(54) DATA-FEEDBACK LOOP FROM PRODUCT LIFECYCLE INTO DESIGN AND MANUFACTURING

(71) Applicant: Siemens Corporation, Iselin, NJ (US)

(72) Inventors: Sanjeev SRIVASTAVA, Princeton Junction, NJ (US); Lucia MIRABELLA, Plainsboro, NJ (US)

(21) Appl. No.: 15/570,403

(22) PCT Filed: May 6, 2016
(86) PCT No.: PCT/US2016/031107

§ 371 Date: Oct. 30, 2017

Related U.S. Application Data
(60) Provisional application No. 62/158,096, filed on May 7, 2015.

(51) Int. Cl. G06Q 10/06; G06F 17/50

(52) U.S. Cl. CPC G06Q 10/067; G06F 17/5009; G06Q 10/063

(57) ABSTRACT

A computer-implemented method for generating an optimal design of a product based on a data-feedback loop from product lifecycle into design and manufacturing information includes using a plurality of product lifecycle models to select an optimal design for the product. Each product lifecycle model corresponds to one of a plurality of product lifecycle stages. During each of the plurality of product lifecycle stages, a product lifecycle dataset is collected from one or more stakeholders using a web-based digital thread and the collected product lifecycle datasets are stored in a database. The plurality of product lifecycle models are up dated using the stored product lifecycle datasets and used to select a new optimal design for the product.

### CROSS-REFERENCE TO RELATED APPLICATIONS

This application claims the benefit of U.S. Provisional Application Ser. No. 62/158,096 filed May 7, 2015, which is incorporated herein by reference in its entirety.

### TECHNICAL FIELD

The present disclosure generally relates to systems, methods, and apparatuses for combining additive manufacturing and conventional manufacturing techniques in a manner that optimizes lifecycle energy usage during the overall manufacturing process.

### BACKGROUND

Currently, tools and methods used in the design of products and systems have very limited or no capacity to support real-time automated or semi-automated guidance for decision making during the product lifecycle (PL), and inclusion of PL consideration in the product conception phase. Early design requirement guidance would enable more producible, serviceable, usable, sustainable, safe and lower-cost designs with shorter product development cycles and fewer design iterations. There is a need for solutions that enable and integrate the wide array of stakeholders across the value chain, including suppliers, OEMs and customers. There is also a need for technologies that can use data from across the product lifecycle and from across the value chain to improve product design and manufacturing. There is also a need for technologies that can track bills of materials throughout the product lifecycle—as designed, as designed for manufacturing, as manufactured, as shipped, as installed, as serviced, as disposed, and so on.

The current solutions are focused within the four walls of one company and are insufficient, too compartmentalized, too costly and too difficult to use across a manufacturing value chain, which goes from design to disposal/recycling of the product. The few available solutions that support decision making from which there is information employed from different parts of the value chain or different parts of the product lifecycle, are typically one-way only with little or no feedback to design from later stages in the lifecycle. The problem of capturing information from multiple product lifecycle stages and use it systematically to improve earlier stages (e.g., design or manufacturing) has not been addressed. Further, how to integrate information and knowledge of lifecycle stages into dynamic modeling environments is an on-going challenge. Moreover, multi-criteria decision support tools are missing in current design systems that allow for rigorous consideration of trade-offs, uncertainty and minimizing the difference between actual and predicted performance.

There is no widely accepted standard for information/knowledge representation that is capable of capturing the full array of lifecycle considerations that are desired in an intelligent and adaptive design environment capable of supporting multi-criteria decision support for consideration of trade-offs and optimal designs from a lifecycle perspective. With the exception of very limited applications, methods are missing for the automated feedback, capture and implementation of rules in real time. Knowledge “owners” have limited or no means for sharing and incorporating expertise/rules in design. To date, solutions have been limited to specific lifecycle considerations and application domains.

Accordingly, it is desired to provide a system which predicts and optimizes lifecycle cost and product quality using digital thread, model-based knowledge and data feedback loop from cradle to grave, and able to dynamically adapt to incoming information.

### SUMMARY

Embodiments of the present invention address and overcome one or more of the above shortcomings and drawbacks, by providing methods, systems, and apparatuses related to the creation and analysis of a data-feedback loop from product lifecycle into design and manufacturing. These techniques and technologies will support design and manufacturing decision makers in understanding tradeoffs between multiple design requirements across the PL and across the value chain.

According to some embodiments of the present invention, a computer-implemented method for generating an optimal design of a product based on a data-feedback loop from product lifecycle into design and manufacturing information includes using a plurality of product lifecycle models to select an optimal design for the product. Each product lifecycle model corresponds to one of a plurality of product lifecycle stages. In some embodiments, each product lifecycle model is optimized based on one or more key performance indicators associated with a corresponding product lifecycle stage. During each of the product lifecycle stages, a product lifecycle dataset is collected from one or more stakeholders using a web-based digital thread and the collected product lifecycle datasets are stored in a database. The plurality of product lifecycle models is updated using the stored product lifecycle datasets and used to select a new optimal design for the product. In some embodiments, at least one of the plurality of product lifecycle models is updated using the collected product lifecycle datasets by modifying one or more model parameters of the at least one of the plurality of product lifecycle models. In other embodiments, the models are updated by modifying a functional form used by the at least one of the plurality of product lifecycle models.

In some embodiments of the aforementioned method, the updating of the plurality of product lifecycle models using the collected product lifecycle datasets is triggered by an update to the stored product lifecycle datasets in the database. In other embodiments, the updating is triggered based on a modification of a process utilized by one of the plurality of product lifecycle stages.

In some embodiments of the aforementioned method, the product lifecycle models are used to select the new optimal design for the product by first identifying a plurality of model alternatives for each of plurality of product lifecycle models. A plurality of alternative combinations of the model alternatives is created. Each alternative combination includes a model alternative for each product lifecycle stage. Next, a simulation of each of the plurality of alternative combinations of the model alternatives is performed over the product lifecycle to yield a plurality of simulation results. Then, the new optimal design is selected based on the plurality of simulation results. In some embodiments, the new optimal design is selected using a multi-objective optimization which is performed across the plurality of simulation results based on one or more key performance indicators associated with product lifecycle stages to identify the new optimal design. In some embodiments, the simulation of each of the plurality of alternative combinations of the model alternatives is performed in parallel across a plurality of processing units.

According to other embodiments, an alternative computer-implemented method for generating an optimal design of a product based on a data-feedback loop from product lifecycle into design and manufacturing information includes, for each of a plurality of viable designs of the product, performing a design evaluation process. This process includes decomposing a viable design into a plurality of features and using the plurality of features to generate an alternatives space comprising a plurality of alternative implementations of a plurality of lifecycle stages associated with the product. In some embodiments, the alternatives space is generated using a plurality of product lifecycle models, each product lifecycle model corresponding to one of the plurality of lifecycle stages. The design evaluation process further includes generating a score for each of the plurality of alternative implementations and selecting a highest scoring alternative implementation for the viable design. Then, the optimal design may be selected from the plurality of viable designs based on a comparison of the highest scoring alternative implementation corresponding to each viable design.

In some embodiments of the aforementioned alternative method, measured data is collected from one or more stakeholders during the plurality of lifecycle stages using a web-based digital thread associated with the product. This measured data may be used in some embodiments to calibrate the plurality of lifecycle models. Following calibration, the design evaluation process may be repeated for each of the plurality of viable designs of the product and a new optimal design may be selected from the plurality of viable designs.

According to other embodiments, a system for generating an optimal design of a product based on a data-feedback loop from product lifecycle into design and manufacturing information includes a software interface, a database, and one or more processors. The software interface is configured to receive measured product lifecycle datasets uploaded by one or more stakeholders during each of a plurality of product lifecycle stages. In some embodiments, the software interface is further configured to facilitate downloading of the measured product lifecycle datasets stored in the database by the one or more stakeholders. The software interface may be implemented, for example, using a Representational State Transfer (REST) software architecture. The database in the system is configured to store the measured product lifecycle datasets uploaded via the software interface. The one or more processors are configured to use a plurality of product lifecycle models to select an optimal design for the product, with each product lifecycle model corresponding to one of the plurality of product lifecycle stages. The processors are further configured to calibrate the plurality of product lifecycle models using the measured product lifecycle datasets. In some embodiments, the product lifecycle models are executed in parallel across the processors during selection of the optimal design for the product.

According to other embodiments, a computer-implemented method for generating an optimal design of a product based on a data-feedback loop from product lifecycle into design and manufacturing information includes performing a design evaluation process for each of a plurality of viable designs of the product. This design evaluation process includes decomposing a viable design into a plurality of features and using the plurality of features to generate an alternatives space comprising a plurality of alternative implementations of a plurality of lifecycle stages associated with the product. The alternative space generated for each of the plurality of viable designs is used to generate a pareto-optimal set of viable designs. Then, the optimal design is selected from the pareto-optimal set based on one or more user-defined preference.

Additional features and advantages of the invention will be made apparent from the following detailed description of illustrative embodiments that proceeds with reference to the accompanying drawings.

### BRIEF DESCRIPTION OF THE DRAWINGS

The foregoing and other aspects of the present invention are best understood from the following detailed description when read in connection with the accompanying drawings. For the purpose of illustrating the invention, there is shown in the drawings embodiments that are presently preferred, it being understood, however, that the invention is not limited to the specific instrumentalities disclosed. Included in the drawings are the following Figures:

FIG. 1 provides a diagram of a system for combining additive manufacturing and conventional manufacturing techniques in a manner that optimizes energy usage during the overall manufacturing process, according to some embodiments;

FIG. 2 provides an flow chart illustrating a computer-implemented method for optimizing a manufacturing plan for a product based on total life cycle energy consumption, according to some embodiments; and

FIG. 3 illustrates an exemplary computing environment within which embodiments of the invention may be implemented.

### DETAILED DESCRIPTION

The following disclosure describes the present invention according to several embodiments directed at methods, systems, and apparatuses related to the creation and analysis data-feedback loop from product lifecycle into design and manufacturing. Briefly, the techniques described herein support design and manufacturing decision makers in understanding tradeoffs between multiple design requirements across the product lifecycle and across the value chain. These techniques combine the use of physics-based and/or data-driven simulation approaches and data acquired through various PL stages to facilitate decision-making and product design optimization.

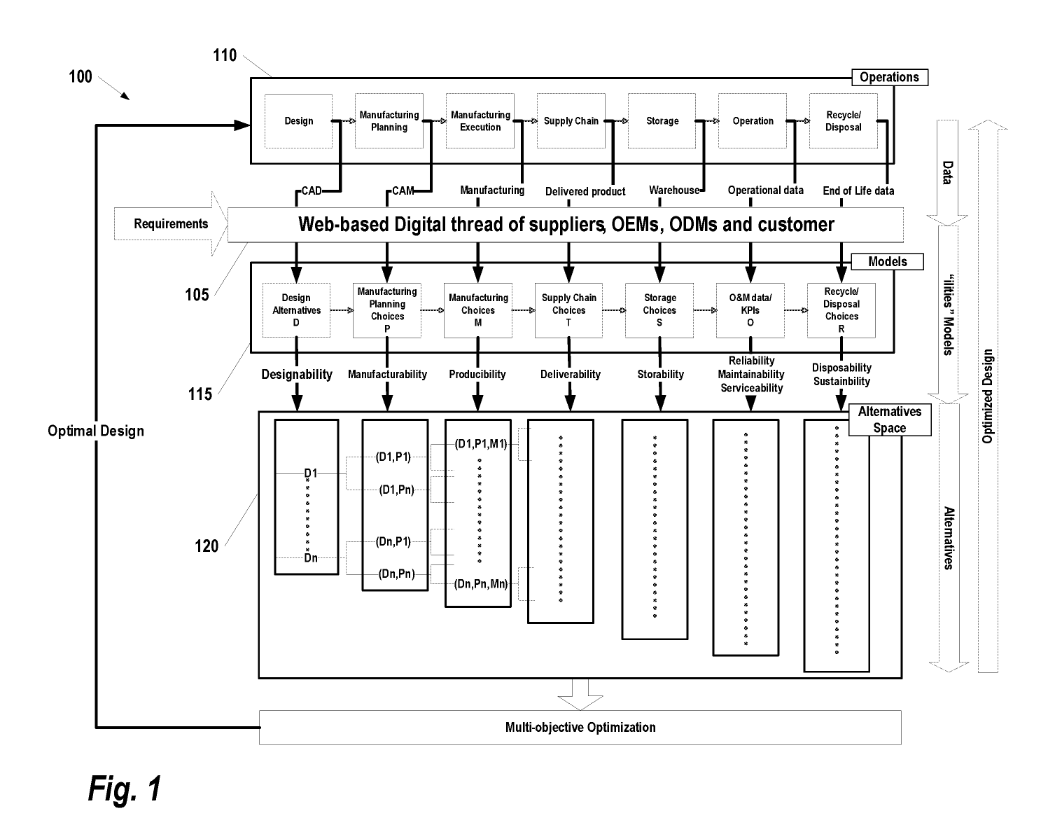

FIG. 1 illustrates a system 100 for incorporating a data-feedback loop from product lifecycle into design and manufacturing, according to some embodiments. The Operations block 110 includes the various PL stages associated with the product. Here, there are seven PL stages illustrated: design, manufacturing planning, manufacturing execution, supply chain, storage, operations, and recycle/disposal. It should be noted that the number and type of PL stages is product dependent. Thus, additional PL stages may be included in the Operations block 110 based on the specifics of each product. For example, the Manufacturing PL stage may be decomposed into PL stages for different types of manufacturing (e.g., non-additive and additive). Additionally, the Operations block 110 for some products may include less PL stages. For example, for a software product, the Recycle/Disposal PL stage may not be relevant.

Each PL stage in the Operations block 110 operates relatively independently (although some of the PL stages may be performed in the same physical location). Each PL stage outputs information, which is used by subsequent stages during the lifecycle. Thus, during the Design PL stage, a computer aided design (CAD) model is created which has specifications on the product design. Based on this CAD model, the Manufacture Planning PL stage develops Computer-aided manufacturing (CAM) information specifying data needed to drive the manufacturing process (e.g., machines to utilize, input data for each machine, etc.). The Manufacturing Execution PL stage manufactures the product based on the CAM information. During the manufacturing process, the Manufacturing PL stage may generate information related to the manufacturing process (e.g., time to complete various stages, power usage, etc.). The Supply Chain PL stage receives the product and distributes to one or more warehouses. During the Supply PL stage, information may be collected such as shipping and transportation costs. Once at the warehouse, the product enters the Storage PL stage and information may be collected such as costs involved with storing the product (e.g., heating or cooling costs, security costs, property costs, etc.). Once the product is distributed to customers, it enters the Operation PL stage. During this stage, information may be collected based on, for example, user surveys, product reviews, returns, repair costs, etc. Finally, once the product reaches the end-of-life, it enters the Recycling/Disposal PL stage where information may be collected involved such as, for example, disposal or recycling costs, environmental impact, etc.

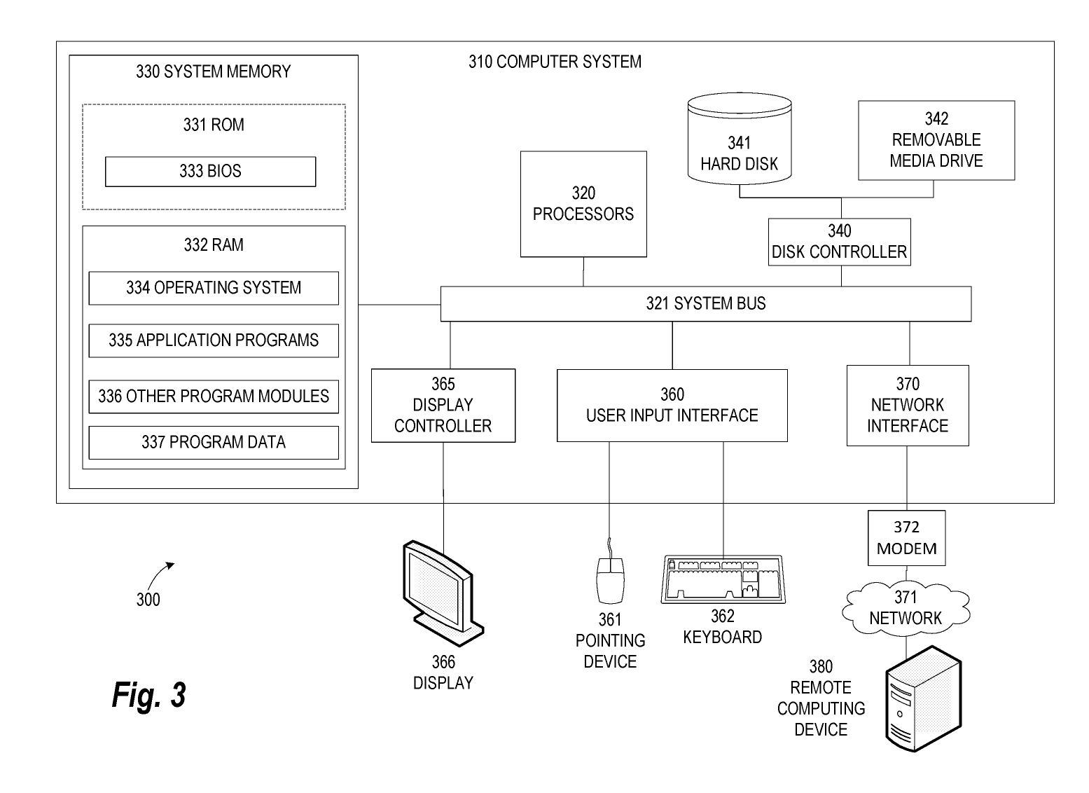

A web-based digital thread 105 is used to collect all the information generated during the PL stages shown in the Operations block 110. The term “digital thread,” as used herein refers to a cross-domain, digital surrogate of the product lifecycle which aggregates information from the various PL stages. The web-based digital thread 105 resides on one or more server computers (see, e.g., FIG. 3) which are accessible over the internet via one or more network interfaces.

As shown in FIG. 1, the web-based digital thread 105 receives data (e.g., bill of materials, cost, pricing, service data, shipping data, etc.) from various actual PL stages, uploaded by different stakeholders (e.g., suppliers, Original Equipment Manufacturers, Original Design Manufacturers, the customer). The web-based digital thread 105 is responsible of providing a software interface for data upload, download (between digital model and actual operations) and exchange (between different PL stages) inside the web-based digital thread 105. Various techniques may be used for implementing the software interface of the web-based digital thread 105. The software interface may be implemented using well-known web standards to allow direct use by the stakeholders. In some embodiments, the software interfaces adhere to Representational State Transfer (REST) architectural constraints. For example, in some embodiments, the webserver(s) running the digital thread may be accessed by appending one or more commands to a base URL such as http:/<runtime_host>/digital_thread/,” where “runtime_host” is the server that is running the digital thread. Thus, to continue with this example, a manufacturing computer may transmit data to the webserver(s) using an HTTP PUT or POST command and the URL “http://<runtime_host>/digital_thread/manufacturing/update.” Similarly, in some embodiments, the REST interface may be extended to allow queries to the web-based digital thread 105 using an HTTP GET command and a particular URL (e.g., “http:/<runtime_host>/digital_thread/manufacturing/data”). It should be noted that the REST interface is only one example of the how the software interface may be implemented. In other embodiments, different web-based interface techniques may be used.

Based on the information collected by the web-based digital thread 105, a plurality of probabilistic and/or deterministic models (shown in “Models” block 115) are developed for desired key performance indicators (KPIs), for example, cost and quality, for each step of the product lifecycle. The desired KPIs can be the measure of “-illities” that are commonly recognized and are critical such as designability; manufacturability; producibility; deliverability; storability; affordability; reliability, maintainability, and serviceability; and disposability and sustainability. These “-illities”, shown below “Models” block 115 in FIG. 1, may be important at only one part of the product lifecycle or may depend on different parts of the product lifecycle.

The models may be implemented using any technique known in the art. For example, in some embodiments, deep learning architectures such as deep neural networks, convolutional deep neural networks, deep belief networks and recurrent neural networks may be applied. A feedback loop is developed to automatically update (calibrate) each model with the data collected, at any time during the lifecycle. The models can be changed in terms of parameters or functional form to better represent the corresponding lifecycle stage at that point in time. The model update can be triggered either by a change in data provided in the web-based digital thread 105 (e.g., due to wear and tear during operations, the product parameters may need to be changed based on the latest service and maintenance data) or by a change in chosen process in a specific PL stage (e.g., change in the mode of transportation at supply chain stage).

An “Alternatives Space” (shown in block 120) representing the various possible combinations of model alternatives from different PL stages will be automatically created and the models for each option of each PL stage will be used to simulate each scenario. A multi-objective optimization problem will be carried out in this space to optimize the considered KPIs for the overall PL, accounting for each stage, while adhering to the product design constraints. Confidence interval on overall KPI will be part of the objective function. This optimization can be performed in the product planning phase, before selecting the design for production. The optimization described above will be continuously carried out during the product lifecycle anytime a change in input data is recorded. In this case, only the decision parameters for future stages of the product lifecycle will be optimized, based on the updated data.

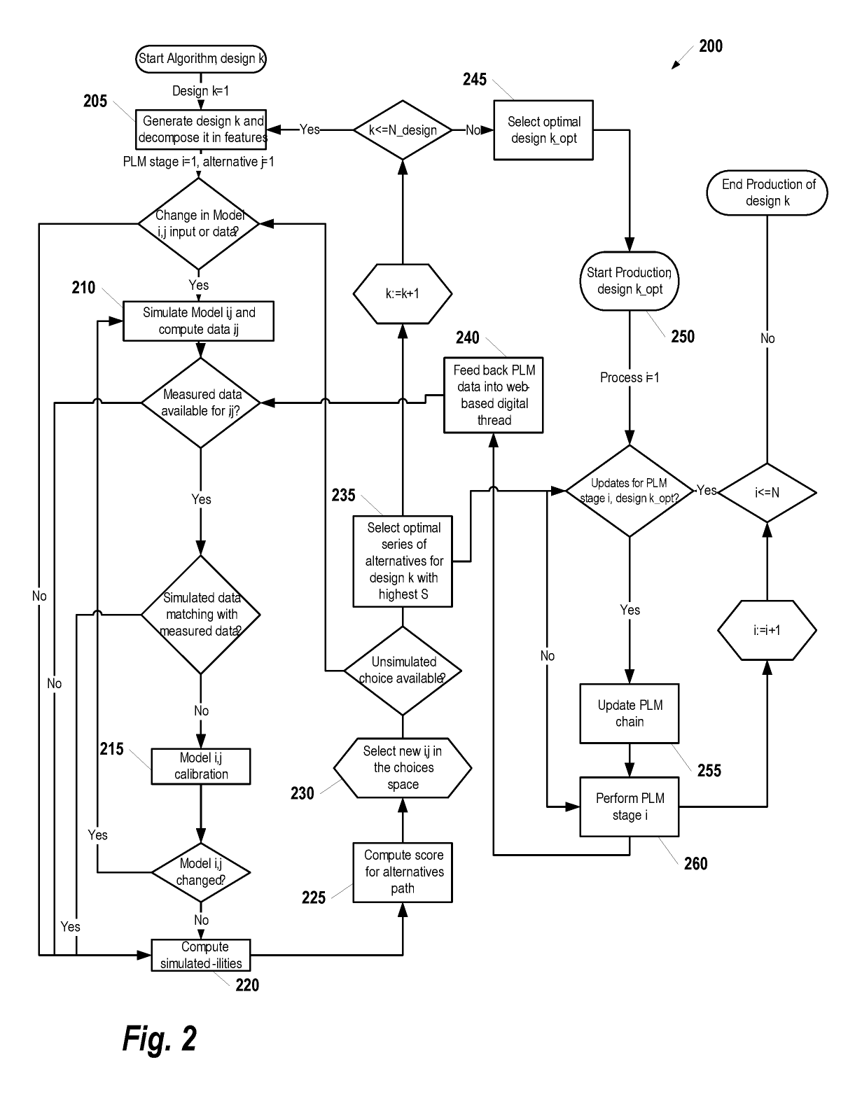

FIG. 2 illustrates a process 200 which incorporates a data-feedback loop from product lifecycle into design and manufacturing, according to some embodiments. An optimal design Dₖ_{ₒₚₜ} is selected through a simulation process that is performed at steps 205 245. In this example, a number of designs {Dₖ}ₖ₌₁^{K} are individually evaluated across a plurality of PL stages {Sᵢ}ᵢ₌₁^{I}. Each PL stage has one or more alternatives {Aⱼ}ⱼ₌₁^{J} that are evaluated in the context of the design being evaluated. At step 205, a viable design Dₖ is generated (or simply received from a database of existing viable designs) and decomposed into features. At step 210, a model is simulated for the current PL stage Sᵢ and current alternative Aⱼ. This model results in simulated output X_{i,j} for the given stage and alternative. The system next determines whether measured output data is also available for the current PL stage Sᵢ and current alternative Aⱼ. If the measured data does not match the model results X_{i,j}, the model is calibrated at step 215 based on the measured data. If the model is changed through the calibration process, the simulation is repeated starting at step 210. In the event that simulated data is not available or the simulated data matches the measured data, the model is used to compute “simulated-ilities” at step 220.

Continuing with reference to FIG. 2, at step 225, a score is computed for each alternative path based on the aggregated KPIs over the product lifecycle. The score will be a cost function based on computed KPIs. For example, it can be a weighted sum of the normalized value of KPIs, where weight measures the importance given to a specific KPI as compared to other KPIs. Alternatively, in other embodiments, a multi-objective optimization is solved where instead of finding one optimal solution, a set of pareto-optimal solutions are computed. At step 230, new values for i and j are selected. If this combination is unsimulated, the process 200 returns to step 210 to perform the simulation. Otherwise, at step 235, the optimal series of alternatives for design are selected based on their individual scores. K is then incremented and, if the maximum number of designs has not been reached steps 205-235 are repeated for the desired number of designs. At step 245, an optimal design Dₖ_{_}ₒₚₜ is selected from {Dₖ}ₖ₌₁^{K} based on the scores determined for each individual design.

Production of the optimal design Dₖ_{_}ₒₚₜ occurs at steps 250-260. Production starts at step 250, for example, by sending specifications on the design Dₖ_{_}ₒₚₜ to a manufacturing facility. Once production is started, each stage of the optimal design {Sᵢ_{_}ₒₚₜ}ᵢ₌₁^{I} in the optimal design Dₖ_{_}ₒₚₜ is sequentially processed at steps 255 and 260. Specifically, at step 255, the current stage of the optimal Sᵢ_{_}ₒₚₜ is updated, if necessary, based on any alternatives from the individual PL stages selected at step 235. Then, at step 260, the stage Sᵢ_{_}ₒₚₜ is performed. Either during or after each stage Sᵢ_{_}ₒₚₜ is performed, Product Lifecycle Management (PLM) data is fed back into the web-based digital thread at step 240 to provide measured data for use in simulation calibration at step 215. Steps 255 and 260 are then repeated for each additional stage in the optimal design Dₖ_{_}ₒₚₜ until production is completed.

FIG. 3 illustrates an exemplary computing environment 300 within which embodiments of the invention may be implemented. For example, this computing environment 300 may be configured to execute the digital thread discussed above with reference to FIG. 1 or to execute portions of the process 200 described above with respect to FIG. 2. Computers and computing environments, such as computer system 310 and computing environment 300, are known to those of skill in the art and thus are described briefly here.

As shown in FIG. 3, the computer system 310 may include a communication mechanism such as a bus 321 or other communication mechanism for communicating information within the computer system 310. The computer system 310 further includes one or more processors 320 coupled with the bus 321 for processing the information. The processors 320 may include one or more central processing units (CPUs), graphical processing units (GPUs), or any other processor known in the art.

The computer system 310 also includes a system memory 330 coupled to the bus 321 for storing information and instructions to be executed by processors 320. The system memory 330 may include computer readable storage media in the form of volatile and/or nonvolatile memory, such as read only memory (ROM) 331 and/or random access memory (RAM) 332. The system memory RAM 332 may include other dynamic storage device(s) (e.g., dynamic RAM, static RAM, and synchronous DRAM). The system memory ROM 331 may include other static storage device(s) (e.g., programmable ROM, erasable PROM, and electrically erasable PROM). In addition, the system memory 330 may be used for storing temporary variables or other intermediate information during the execution of instructions by the processors 320. A basic input/output system (BIOS) 333 containing the basic routines that helps to transfer information between elements within computer system 310, such as during start-up, may be stored in ROM 331. RAM 332 may contain data and/or program modules that are immediately accessible to and/or presently being operated on by the processors 320. System memory 330 may additionally include, for example, operating system 334, application programs 335, other program modules 336 and program data 337.

The computer system 310 also includes a disk controller 340 coupled to the bus 321 to control one or more storage devices for storing information and instructions, such as a hard disk 341 and a removable media drive 342 (e.g., floppy disk drive, compact disc drive, tape drive, and/or solid state drive). The storage devices may be added to the computer system 310 using an appropriate device interface (e.g., a small computer system interface (SCSI), integrated device electronics (IDE), Universal Serial Bus (USB), or FireWire).

The computer system 310 may also include a display controller 365 coupled to the bus 321 to control a display 366, such as a cathode ray tube (CRT) or liquid crystal display (LCD), for displaying information to a computer user. The computer system includes an input interface 360 and one or more input devices, such as a keyboard 362 and a pointing device 361, for interacting with a computer user and providing information to the processor 320. The pointing device 361, for example, may be a mouse, a trackball, or a pointing stick for communicating direction information and command selections to the processor 320 and for controlling cursor movement on the display 366. The display 366 may provide a touch screen interface which allows input to supplement or replace the communication of direction information and command selections by the pointing device 361.

The computer system 310 may perform a portion or all of the processing steps of embodiments of the invention in response to the processors 320 executing one or more sequences of one or more instructions contained in a memory, such as the system memory 330. Such instructions may be read into the system memory 330 from another computer readable medium, such as a hard disk 341 or a removable media drive 342. The hard disk 341 may contain one or more datastores and data files used by embodiments of the present invention. Datastore contents and data files may be encrypted to improve security. The processors 320 may also be employed in a multi-processing arrangement to execute the one or more sequences of instructions contained in system memory 330. In alternative embodiments, hard-wired circuitry may be used in place of or in combination with software instructions. Thus, embodiments are not limited to any specific combination of hardware circuitry and software.

As stated above, the computer system 310 may include at least one computer readable medium or memory for holding instructions programmed according to embodiments of the invention and for containing data structures, tables, records, or other data described herein. The term “computer readable medium” as used herein refers to any medium that participates in providing instructions to the processor 320 for execution. A computer readable medium may take many forms including, but not limited to, non-volatile media, volatile media, and transmission media. Non-limiting examples of non-volatile media include optical disks, solid state drives, magnetic disks, and magneto-optical disks, such as hard disk 341 or removable media drive 342. Non-limiting examples of volatile media include dynamic memory, such as system memory 330. Non-limiting examples of transmission media include coaxial cables, copper wire, and fiber optics, including the wires that make up the bus 321. Transmission media may also take the form of acoustic or light waves, such as those generated during radio wave and infrared data communications.

The computing environment 300 may further include the computer system 310 operating in a networked environment using logical connections to one or more remote computers, such as remote computer 380. Remote computer 380 may be a personal computer (laptop or desktop), a mobile device, a server, a router, a network PC, a peer device or other common network node, and typically includes many or all of the elements described above relative to computer system 310. When used in a networking environment, computer system 310 may include modem 372 for establishing communications over a network 371, such as the Internet. Modem 372 may be connected to bus 321 via user network interface 370, or via another appropriate mechanism.

Network 371 may be any network or system generally known in the art, including the Internet, an intranet, a local area network (LAN), a wide area network (WAN), a metropolitan area network (MAN), a direct connection or series of connections, a cellular telephone network, or any other network or medium capable of facilitating communication between computer system 310 and other computers (e.g., remote computer 380). The network 371 may be wired, wireless or a combination thereof. Wired connections may be implemented using Ethernet, Universal Serial Bus (USB), RJ-11 or any other wired connection generally known in the art. Wireless connections may be implemented using Wi-Fi, WiMAX, and Bluetooth, infrared, cellular networks, satellite or any other wireless connection methodology generally known in the art. Additionally, several networks may work alone or in communication with each other to facilitate communication in the network 371.

In some embodiments, the computer system 300 may be utilized in conjunction with a parallel processing platform comprising a plurality of processing units. This platform may allow parallel execution of one or more of the tasks associated with optimal design generation, as described above. For the example, in some embodiments, execution of multiple product lifecycle simulations may be performed in parallel, thereby allowing reduced overall processing times for optimal design selection.

The embodiments of the present disclosure may be implemented with any combination of hardware and software. In addition, the embodiments of the present disclosure may be included in an article of manufacture (e.g., one or more computer program products) having, for example, computer-readable, non-transitory media. The media has embodied therein, for instance, computer readable program code for providing and facilitating the mechanisms of the embodiments of the present disclosure. The article of manufacture can be included as part of a computer system or sold separately.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

An executable application, as used herein, comprises code or machine readable instructions for conditioning the processor to implement predetermined functions, such as those of an operating system, a context data acquisition system or other information processing system, for example, in response to user command or input. An executable procedure is a segment of code or machine readable instruction, sub-routine, or other distinct section of code or portion of an executable application for performing one or more particular processes. These processes may include receiving input data and/or parameters, performing operations on received input data and/or performing functions in response to received input parameters, and providing resulting output data and/or parameters.

A graphical user interface (GUI), as used herein, comprises one or more display images, generated by a display processor and enabling user interaction with a processor or other device and associated data acquisition and processing functions. The GUI also includes an executable procedure or executable application. The executable procedure or executable application conditions the display processor to generate signals representing the GUI display images. These signals are supplied to a display device which displays the image for viewing by the user. The processor, under control of an executable procedure or executable application, manipulates the GUI display images in response to signals received from the input devices. In this way, the user may interact with the display image using the input devices, enabling user interaction with the processor or other device.

The functions and process steps herein may be performed automatically or wholly or partially in response to user command. An activity (including a step) performed automatically is performed in response to one or more executable instructions or device operation without user direct initiation of the activity.

The system and processes of the figures are not exclusive. Other systems, processes and menus may be derived in accordance with the principles of the invention to accomplish the same objectives. Although this invention has been described with reference to particular embodiments, it is to be understood that the embodiments and variations shown and described herein are for illustration purposes only. Modifications to the current design may be implemented by those skilled in the art, without departing from the scope of the invention. As described herein, the various systems, subsystems, agents, managers and processes can be implemented using hardware components, software components, and/or combinations thereof. No claim element herein is to be construed under the provisions of 35 U.S.C. 112, sixth paragraph, unless the element is expressly recited using the phrase “means for.”

1. A computer-implemented method for automatically generating an optimal design of a product based on a data-feedback loop from product lifecycle into design and manufacturing information, the method comprising:
receiving in a web-based digital thread data from a plurality of product lifecycle stages, the web-based digital thread configured to exchange the data between different product lifecycle stages;
using a plurality of product lifecycle models to select an optimal design for the product, each product lifecycle model corresponding to one of a plurality of product lifecycle stages and configured to use the data in the web-based digital thread as input to each of the plurality of models;
storing the data for each product lifecycle stage collected in the web-based digital thread in a database;
automatically updating at least one of the plurality of product lifecycle models using the stored product lifecycle datasets during any time during the produce lifecycle; and
using the updated plurality of product lifecycle models to select a new optimal design for the product.

2. The method of claim 1, wherein each product lifecycle model is optimized based on one or more key performance indicators associated with a corresponding product lifecycle stage.

3. The method of claim 1, wherein at least one of the plurality of product lifecycle models is updated using the collected product lifecycle datasets by:
modifying one or more model parameters of the at least one of the plurality of product lifecycle models.

4. The method of claim 1, wherein at least one of the plurality of product lifecycle models is updated using the collected product lifecycle datasets by:
modifying a functional form used by the at least one of the plurality of product lifecycle models.

5. The method of claim 1, wherein the updating of the plurality of product lifecycle models using the collected product lifecycle datasets is triggered by an update to the stored product lifecycle datasets in the database.

6. The method of claim 1, wherein the updating of the plurality of product lifecycle models using the collected product lifecycle datasets is triggered based on a modification of a process utilized by one of the plurality of product lifecycle stages.

7. The method of claim 1, wherein using the plurality of product lifecycle models to select the new optimal design for the product comprises:
identifying a plurality of model alternatives for each of plurality of product lifecycle models;
creating a plurality of alternative combinations of the model alternatives, each alternative combination comprising a model alternative for each product lifecycle stage;
performing a simulation of each of the plurality of alternative combinations of the model alternatives over the product lifecycle to yield a plurality of simulation results; and
selecting the new optimal design based on the plurality of simulation results.

8. The method of claim 7, wherein the simulation of each of the plurality of alternative combinations of the model alternatives is performed in parallel across a plurality of processing units.

9. The method of claim 7, wherein selection of the new optimal design based on the plurality of simulation results is performed by:
performing a multi-objective optimization across the plurality of simulation results based on one or more key performance indicators associated with product lifecycle stages to identify the new optimal design.

10. A computer-implemented method for automatically generating an optimal design of a product based on a data-feedback loop from product lifecycle into design and manufacturing information, the method comprising:
receiving data from a plurality of product lifecycle stages in a web-based digital thread;
for each of a plurality of viable designs of the product, performing a design evaluation process comprising:
decomposing a viable design into a plurality of features,
using the plurality of features to generate an alternatives space comprising a plurality of alternative implementations of a plurality of lifecycle stages associated with the product, wherein the plurality of features is automatically updated from the received data in the web-based digital thread during any of the product lifecycle stages,
generating a score for each of the plurality of alternative implementations, and
selecting a highest scoring alternative implementation for the viable design; and
selecting the optimal design from the plurality of viable designs based on a comparison of the highest scoring alternative implementation corresponding to each viable design.

11. The method of claim 10, wherein the alternatives space is generated using a plurality of product lifecycle models, each product lifecycle model corresponding to one of the plurality of lifecycle stages.

12. The method of claim 11, further comprising:
collecting measured data from one or more stakeholders during the plurality of lifecycle stages using a web-based digital thread associated with the product.

13. The method of claim 12, further comprising:
using the measured data to calibrate the plurality of lifecycle models.

14. The method of claim 13, further comprising:
following calibration, repeating the design evaluation process for each of the plurality of viable designs of the product; and
selecting a new optimal design from the plurality of viable designs.

15. The method of claim 10, wherein the score for each of the plurality of alternative implementations is determined based on key product indicators associated with the plurality of lifecycle stages.

16. A system for automatically generating an optimal design of a product based on a data-feedback loop from product lifecycle into design and manufacturing information, the system comprising:
a software interface configured to receive measured product lifecycle datasets uploaded by one or more stakeholders during each of a plurality of product lifecycle stages;
a database configured to store the measured product lifecycle datasets uploaded via the software interface; and
one or more processors configured to:
use a plurality of product lifecycle models to select an optimal design for the product, each product lifecycle model corresponding to one of the plurality of product lifecycle stages, and automatically calibrate the plurality of product lifecycle models using the measured product lifecycle datasets during any of the product lifecycle stages.

17. The system of claim 16, wherein the software interface is further configured to facilitate downloading of the measured product lifecycle datasets stored in the database by the one or more stakeholders.

18. (canceled)

19. The system of claim 16, wherein the optimal design is selected based on simulated key product indicators generated by the plurality of product lifecycle models.

20. The system of claim 16, wherein the plurality of product lifecycle models are executed in parallel across the one or more processors during selection of the optimal design for the product.

21. A computer-implemented method for automatically generating an optimal design of a product based on a data-feedback loop from product lifecycle into design and manufacturing information, the method comprising:
receiving data from a plurality of product lifecycle stages in a web-based digital thread;
for each of a plurality of viable designs of the product, performing a design evaluation process comprising:
decomposing a viable design into a plurality of features,
using the plurality of features to generate an alternatives space comprising a plurality of alternative implementations of a plurality of lifecycle stages associated with the product, wherein the plurality of features is automatically updated from the received data in the web-based digital thread during any of the product lifecycle stages;
using the alternative space generated for each of the plurality of viable designs, generating a pareto-optimal set of viable designs; and
selecting the optimal design from the pareto-optimal set based on one or more user-defined preference.
